(19) United States
(12) Patent Application Publication
(10) Pub. No.: US 2016/0365524 A1
(43) Pub. Date: Dec. 15, 2016

(54) ORGANIC DIODE

(71) Applicant: Cambridge Display Technology Limited, Godmanchester (GB)

(72) Inventors: Thomas Kugler, Cambridge (GB); Andrey Nikolaenko, Huntington (GB)

(73) Assignee: Cambridge Display Technology Limited, Godmanchester (GB)

(21) Appl. No.: 15/175,206

(22) Filed: Jun. 7, 2016

(30) Foreign Application Priority Data
Jun. 15, 2015 (GB) 1510423.5

(51) Int. Cl. H01L 51/05; H01L 51/00; H01L 51/10

(52) U.S. Cl. CPC H01L 51/0575; H01L 51/105; H01L 51/0003; H01L 2251/308; H01L 51/0039

(57) ABSTRACT

A rectifier diode which does not emit light in operation comprises:
an anode layer;
a work function modification layer comprising a salt compound;
an organic charge transport layer;
an optional electron injection layer; and
   a cathode layer.

Also provided is a method for producing the organic diode.

### RELATED APPLICATIONS

This application claims the benefits under 35 U.S.C. §119(a)-(d) or 35 U.S.C. §365(b) of British application number GB 11510423.5, filed Jun. 15, 2015, the entirety of which is incorporated herein.

### FIELD OF THE INVENTION

The present invention relates to an electronic device, in particular a rectifier diode which does not emit light, and a method of producing said device.

### BACKGROUND

Organic electronic devices provide many potential advantages including inexpensive, low temperature, large scale fabrication on a variety of substrates including glass and plastic. Examples of such devices include organic light emitting diodes (OLEDs), light emitting electrochemical cells (LECs) and electron only devices (EODs).

The organic electronic devices have very broad commercial applications. For example, organic light emitting diodes may be used in applications such as flat panel displays and solid-state lighting, and organic solar cells may be employed in renewable energy applications. In addition, electron only devices may be used as organic rectifier diodes in applications such as radio frequency identification (RFID) transponders.

An organic rectifier diode lets electrical current flow in only one direction and is mainly used for power supply operation. Rectifier diodes can handle higher current flow than regular diodes and are generally used in order to change alternating current into direct current. They are designed as discrete components or as integrated circuits and are usually fabricated from silicon and characterized by a fairly large P-N-junction surface. This results in high capacitance under reverse-bias conditions. In high-voltage supplies, two rectifier diodes or more may be connected in series in order to increase the peak-inverse-voltage (PIV) rating of the combination.

RFID transponders are increasingly being employed for providing merchandise, articles or security products with information that can be read out electronically, They are thus being employed for example as an electronic bar code for consumer goods, as luggage tags for identifying luggage, or as security elements that are incorporated into the binding of a passport and stores authentication information.

Passive RFID systems take their energy from the irradiated alternating field. The possible distance between the reader and transponder in this case depends on the emitted power and the energy demand of the transponder. Products which contain a silicon-based chip are too expensive for many applications. For example, a silicon-based identification tag is out of the question for the identification of foodstuffs due to price, expiry date, and the like.

Polymers and/or organic semiconductors on the other hand offer the potential of being able to use cheap printing techniques for their structuring and application.

To make the carrier frequency of the RFID system usable for power supply, the power supply must be rectified. In a simplest case a diode (half-wave rectification) and for more complex applications several diodes are used (2 diodes: full-wave circuit with center tap of the transformer; 4 diodes: Graetz circuit). A rectifier can thus be only a single diode, contain several diodes and/or additionally have a capacitor.

However, problems with existing EODs suitable in RFIDs include a high turn-on voltage as well as ow current densities, which lead to rectification ratios still insufficient for the desired applications. Therefore, improved EODs are desired with lower turn-on voltage and high current densities.

### BRIEF DESCRIPTION OF THE DRAWINGS

FIG. 1 is a schematic structure of an electron only device of the invention.

FIG. 2 shows the current density vs voltage graphs for electron only devices used in the example.

FIG. 3 shows the current density vs voltage graphs for electron only devices with varying work function modification thicknesses.

FIG. 4 illustrates the voltage stability of electron only devices with time at two different fixed current densities.

FIG. 5 shows the current density vs voltage graphs for electron only devices with varying organic charge transport layer thicknesses.

### SUMMARY OF INVENTION

The present invention provides an electronic device comprising:
an anode layer;
a work function modification layer comprising a salt compound as defined herein;
an organic charge transport layer;
an optional electron injection layer; and
a cathode layer.

The electronic device is a rectifier diode which does not emit light in operation, preferably an electron only device.

The present invention also provides a method of producing the above device comprising the steps of:
providing an anode layer;
depositing a work function modification layer comprising a salt compound as defined herein;
depositing an organic charge transport layer;
optionally depositing an electron injection layer; and
depositing a cathode layer.

Preferred embodiments are set forth in the subclaims.

### DEFINITIONS

As used herein the term “electrode” refers to an anode or a cathode.

As used herein the term “ink” refers to a composition comprising conductive particles, a resin and a solvent.

As used herein the term “resin” is used to refer to a polymer which forms a continuous matrix in which the conductive particles can be dispersed.

As used herein the term “screen printing” refers to a process wherein a squeegee or blade is used to apply force or pass ink through a mesh which has areas of the mesh blocked in a patternwise fashion so that the ink is transferred through the mesh to an underlying substrate forms a negative of the blocked pattern on the mesh.

As used herein the term “vapour deposition” refers to thermal evaporation in a vacuum.

As used herein the term “polymer” refers to a compound comprising repeating units. Polymers usually have a polydispersity of greater than 1.

As used herein the term “charge transporting polymer” refers to a polymer that can transport holes or electrons. The invention is particularly focused on electron-only devices that use electrons as charge carriers.

As used herein the term “polar” refers to a separation of charge within the structure of a molecule. “Polar groups” are those groups wherein there is a covalent bond between two atoms wherein the electrons forming the bond are unequally distributed. The term encompasses electrical dipole moments where the distribution of charge in the bond is only slightly uneven creating a slightly positive end and a slightly negative end. The term also encompasses zwitterions and ionic groups where the charge separation is complete.

As used herein the term “salt” refers to an ionic substance comprising a cation and a counteranion.

As used herein the term “cross linkable group” refers to a group comprising an unsaturated bond or a precursor capable of in situ formation of an unsaturated bond that can undergo a bond-forming reaction.

As used herein the term “alkyl” refers to saturated, straight chained, branched or cyclic groups. Alkyl groups may be substituted or unsubstituted.

As used herein the term “haloalkyl” refers to saturated, straight chained, branched or cyclic groups in which one or more hydrogen atoms are replaced by a halogen atom, e.g. F or Cl, especially F.

As used herein, the term “cycloalkyl” refers to a saturated or partially saturated mono- or bicyclic alkyl ring system containing 3 to 10 carbon atoms. Cycloalkyl groups may be substituted or unsubstituted.

As used herein, the terms “heterocycloalkyl” and “heterocyclic” refers to a cycloalkyl group in which one or more ring carbon atoms are replaced by at least one hetero atom such as —O—, —N— or —S—. Heterocycloalkyl groups may be substituted or unsubstituted.

As used herein the term “alkenyl” refers to a straight chained, branched or cyclic group comprising a double bond. Alkenyl groups may be substituted or unsubstituted.

As used herein the term “alkynyl” refers to straight chained, branched or cyclic groups comprising a triple bond. Alkynyl groups may be substituted or unsubstituted.

Optional substituents that may be present on alkyl, cycloalkyl, heterocycloalkyl, alkenyl and alkynyl groups as well as the alkyl moiety of an arylalkyl group include C₁₋₁₆ alkyl or C₁₋₁₆ cycloalkyl wherein one or more non-adjacent C atoms may be replaced with O, S, N, C═O and —COO—, substituted or unsubstituted C₅₋₁₄ aryl, substituted or unsubstituted C₅₋₁₄ heteroaryl, C₁₋₁₆ alkoxy, C₁₋₁₆ alkylthio, halo, e.g. fluorine and chlorine, cyano and arylalkyl.

As used herein, the term “aryl” refers to a group comprising at least one aromatic ring. The term aryl encompasses heteroaryl as well as fused ring systems wherein one or more aromatic ring is fused to a cycloalkyl ring. Aryl groups may be substituted or unsubstituted.

As used herein, the term “heteroaryl” refers to a group comprising at least one aromatic ring in which one or more ring carbon atoms are replaced by at least one hetero atom such as —O—, —N— or —S—.

Optional substituents that may be present on aryl or heteroaryl groups as well as the aryl moiety of arylalkyl groups include halide, cyano, C₁₋₁₆ alkyl, C₁₋₁₆ fluoroalkyl, C₁₋₁₆ alkoxy, C₁₋₁₆ fluoroalkoxy, C₅₋₁₄ aryl and C₅₋₁₄ heteroaryl.

As used herein, the term “arylalkyl” refers to an alkyl group as hereinbefore defined that is substituted with an aryl group as hereinbefore defined.

As used herein, the term “heteroarylalkyl” refers to an alkyl group as hereinbefore defined that is substituted with a heteroaryl group as hereinbefore defined.

As used herein the term “halogen” encompasses atoms selected from the group consisting of F, Cl, Br and I.

As used herein the term “alkoxy” refers to O-alkyl groups, wherein alkyl is as defined above.

As used herein the term “aryloxy” refers to O-aryl groups, wherein aryl is as defined above.

As used herein the term “arylalkoxy” refers to O-arylalkyl groups, wherein arylalkyl is as defined above.

As used herein the term “alkylthio” refers to S-alkyl groups, wherein alkyl is as defined above.

As used herein the term “arylthio” refers to S-aryl groups, wherein aryl is as defined above.

As used herein the term “arylalkylthio” refers to S-arylalkyl groups, wherein arylalkyl are as defined above.

As used herein the term “dry nitrogen atmosphere” refers to an atmosphere of nitrogen having less than about 10 ppm O₂ and water content.

### DESCRIPTION OF THE INVENTION

The present invention provides an electronic device as defined in the claims, comprising:
an anode layer;
a work function modification layer comprising a salt compound selected among alkali metal salts, and salts with organic cations comprising at least 3 carbon atoms, such as tetraalkylammonium salts, tetraalkylphosphonium salts, trialkylsulfonium salts, pyridinium salts and immidazolium salts in contact with the anode layer and operable to decrease the workfunction of the anode layer to block hole injection from the anode;
an organic charge transport layer;
an optional electron injection layer; and
a cathode layer.

Advantageously, with the present invention, an electronic device is provided which is suitable as an electron only device with low turn-on voltage and high current densities. A thin work function modification layer is deposited on the anode layer and effectively blocks hole injection at the anode interface by reducing the work function of the anode material and thereby prevents the injection of holes from the anode into the organic charge transport layer.

The salt compound as employed in accordance with the present invention in the work function modification layer is selected among alkali metal salts as well as salts comprising large mono- or divalent organic cations, typically organic cations comprising at least 3 carbon atoms, such as tetraalkylammonium, tetraalkylphosphonium, trialkylsulfonium, pyridinium and imidazolium. The alkali metal salts are selected among lithium salts, sodium salts, potassium salts, rubidium salts as well as cesium salts. Suitable anions for these alkali metal salts are carbonates, carboxylates, dihydrogen phosphates, hydrogen phosphates, and phosphates and phosphonates. Suitable carboxylates are anions of carboxylic acids with from 2 to 10 carbon atoms, preferably 2 to 6. Preferred among the alkali metal salts are alkali carbonates and, in particular, cesium carbonate. As mentioned above, suitable cations for the organic cations are in particular tetraalkylammonium, tetraalkylphosphonium, trialkylsulfonium, pyridinium and imidazolium. The alkyl groups in the cations mentioned above preferably are identical in the respective cation, although the present invention also contemplates the use of such cations carrying different alkyl residues. Suitable examples of alkyl residues are in particular alkyl groups with 1 to 8 carbon atoms, preferably 1 to 6 carbon atoms, more preferably 1 to 4 carbon atoms, including in particular methyl, ethyl, propyl and butyl. The anions for these salt compounds preferably are selected among the anions identified above as suitable anions for the alkali metal salts. Preferred are again the carbonates of the cations mentioned above.

The anions are chosen to have a strong interaction with the anode, which typically comprises indium tin oxide. Without wishing to be bound by the theory, such an anion, together with a large cation, is likely to promote orientation of the dipole moment of the molecules in the workfunction modification layer. In other words the workfunction modification mechanism is surface dipole formation.

The thickness of the work function modification layer is preferably 10 nm or less, more preferably 8 nm or less, and even more preferably 5 nm or less. The voltage stability of the organic device of the present invention depends on the current density but does not depend on the thickness of the work function modification layer on the anode. Very thin work function modification layer in accordance with the present invention are effective in blocking hole injection by lowering the work function of the anode material while not having any detrimental effect on the voltage stability of the device.

The organic device of the present invention may optionally comprise an electron injection layer between the organic charge transport layer and the cathode layer. Any suitable material used as an electron injection layer in organic luminescent devices may be also used in the device of the present invention. However, preferably, the electron injection layer comprises an alkali-metal halogenide, more preferably an alkali-metal fluoride, such as potassium fluoride or sodium fluoride. Most preferred is the electron injection layer comprising sodium fluoride.

The anode can be formed from any suitable material used in organic electronic devices. Preferably, the anode layer comprises indium tin oxide (ITO), indium zinc oxide (IZO), metals such as Ni, or polymers such as polyaniline and polyethylenedioxythiophene. More preferred is the anode layer being an ITO layer.

Preferably the anode is transparent. Preferably the ITO or IZO present in the anode is deposited by solution processing e.g. printing, preferably screen printing, or by thermal evaporation. The anode is preferably 20 to 200 nm thick and more preferably 10 to 100 nm thick.

The cathode can be formed from any suitable material used in organic electronic devices. Preferably, the cathode comprises at least one of Ag, Al, Au, Cd, Cr, Cu, Ga, In, Li, Ni, Pb, Pt, Sn, Ti and Zn. More preferred are Ag, Al, Au, Ni and Pt, with Ag, Al and Au being even more preferred.

In order to provide efficient injections of electrons into the device, the cathode preferably has a work function of less than 3.5 eV, more preferably less than 3.2 eV, most preferably less than 3 eV. Work functions of metals can be found in, for example, Michaelson, J. Appl. Phys 48(11), 4729, 1977.

The cathode layer preferably comprises one or more resins. A resin may be present when screen printing is used to deposit the cathode. The resin is preferably a polymer. The polymer may be a thermoplastic polymer or a thermosetting polymer. Optionally the resin is crosslinked. Preferably the resin comprises an alkyl cellulose, a poly(meth)acrylic, a poly(meth)acrylate, a styrene, an acrylamide, a vinyl ether, a polyvinyl alcohol or mixtures thereof. Still more preferably the resin comprises an alkyl cellulose, a poly(meth)acrylic, a poly(meth)acrylate or mixtures thereof. Suitable resins for use in the methods and inks of the present invention are commercially available from, for example, Sigma Aldrich. The purpose of the resin is to provide a continuous matrix for the carbon particles during printing so that when the printed ink is subsequently heated, the carbon particles fuse to form a continuous carbon track. Preferably the cathode comprises 10-99 wt % carbon and 1-90 wt % resin. More preferably the cathode comprises 25-99 wt % carbon and 1-75 wt % resin, still more preferably 50-99 wt % carbon and 1-50 wt % resin.

In another embodiment of the invention, the cathode layer comprises substantially no resin. In this case, the cathode layer is preferably formed by vapour deposition.

In another preferred embodiment of the invention, the device comp rises a cathode layer which does not comprise a low work function metal. Preferably the cathode layer contains substantially no Ag, Al, Na, or salts, alloys or mixtures thereof.

The cathode layer of the device structures of the present invention may be deposited by any suitable method. The cathode may, for example, be deposited by vapour deposition. Suitable methods include thermal evaporation, e-beam evaporation and sputtering. In such embodiments, the cathode contains substantially no resin and substantially no solvent. Alternatively, the cathode may be deposited by depositing an ink. In another embodiment, preferably the cathode layer is deposited by printing. Suitable printing methods include screen printing, gravure printing, dispense printing, nozzle printing, flexographic printing, roll to roll printing, dip coating, slot die coating, doctor blade coating or ink-jet printing. Screen printing is particularly preferred. Printing, and in particular screen printing, is a highly advantageous process as it enables large area patterning on flexible substrates at relatively low cost.

In one embodiment, the device comprises an optional substrate. If present the substrate may comprises a plastic film such as transparent polyethylene terephthalate (PET), polybutylene terephthalate (PBT), polyethylene naphthalate (PEN), polycarbonate (PC), polyimides (PI), polysulfones (PSO), and poly (p-phenylene ether sulfone) (PES). Alternatively, materials such as A thin substrate comprising glass or other materials such as a composite stack comprising glass and polymer or polymer comprises films coated with inorganic barrier layers, is also suitable. The thickness of the optional substrate is about 20-300 μm, preferably 30 to 200 μm.

In the electronic device of the present invention, the organic charge transport layer comprises a conducting material. Any suitable organic conducting material can be used for the organic charge transport layer of the present invention which is known as a suitable material for such layers in the art of electronic devices. However, preferably, the organic charge transport layer comprises a conducting material which is polymeric.

The organic charge transport layer comprises a charge transporting polymer.

Optionally the charge transporting polymer may be a polymer or copolymer comprising monomers comprising substituted or unsubstituted fluorene, phenanthrene or propellane monomers, for example polyfluorene or polyphenanthrene.

The charge transporting polymer may comprise a polar group. More preferably the charge transporting polymer present in the organic charge transport layer comprises a repeat unit of formula (Xa) or (Xb):

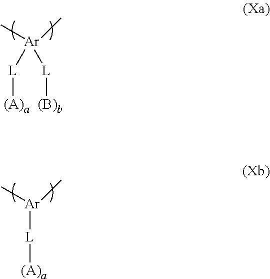

wherein Ar is a C₅₋₂₀ substituted or unsubstituted aryl or heteroaryl group;
L is a bond or a linker group;
A is a polar group;
B is a A, hydrogen, substituted or unsubstituted C₁₋₁₆ alkoxy, substituted or unsubstituted C₅₋₁₄ aryl, substituted or unsubstituted arylalkyl, substituted or unsubstituted C₅₋₁₄ heteroaryl, substituted or unsubstituted heteroarylalkyl and substituted or unsubstituted C₁₋₁₆ alkyl wherein one or more non-adjacent C atoms may be replaced with —O—, —NR—, —NH—, —S—, —COO—, —NHCO—, —NHSO₂—, —NHCOO-groups wherein R is C₁₋₈ alkyl; and
each of a and b are independently an integer selected from 1 to 5.

When either of a or b is greater than 1, there are more than 1 A and B groups respectively attached to the linker, e.g. when a is 2, there are 2 A groups attached to the linker. When multiple A and/or B groups are present, they may be attached to the linker at different atoms.

Preferred charge transporting polymers comprise a repeat unit of formula X shown below:

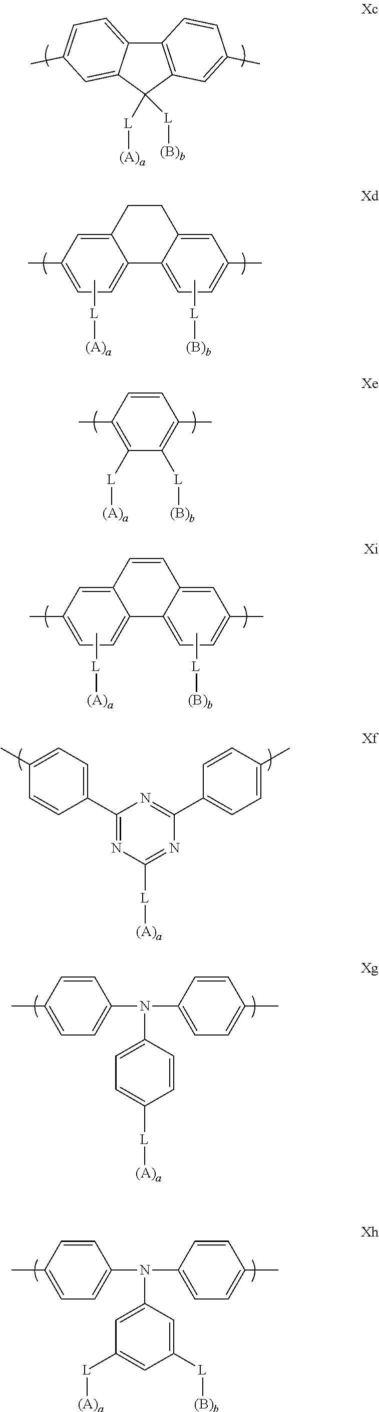

wherein L, A, B, a and b are as defined above in relation to formula Xa and Xb.

Particularly preferably the charge transporting polymer comprises repeat units of formula (Xc):

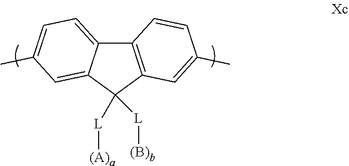

wherein L, A, B, a and b are as defined above in relation to formula Xa and Xb.

In preferred charge transporting polymers, (B)_{b} is (A)ₐ, i.e. the repeat unit comprises identical polar groups per unit. In further preferred charge transporting polymers a is 1 or 2.

In further preferred charge transporting polymers, L is a linker group selected from substituted or unsubstituted C₅₋₁₄ aryl, substituted or unsubstituted C₅₋₁₄ heteroaryl and substituted or unsubstituted C₁₋₁₆ alkyl wherein one or more non-adjacent C atoms may be replaced with —O—, —NR—, —NH—, —S—, —COO—, —NHCO—, —NHSO₂—, —NHCOO— groups wherein R is C₁₋₈ alkyl. More preferably L is a linker group selected from substituted or unsubstituted C₅₋₁₄ aryl and substituted or unsubstituted C₁₋₁₆ alkyl wherein one or more non-adjacent C atoms may be replaced with —O—, —NR—, —NH—, —S—, —COO—, —NHCO—, —NHSO₂—, —NHCOO-groups wherein R is C₁₋₆ alkyl. In some charge transporting polymers, L is a C₅₋₁₄ aryl, especially a C₅ or C₆ aryl, e.g. phenyl. In other charge transporting polymers, L is a C₁₋₁₆ alkyl, more preferably a C₁₋₆ alkyl and yet more preferably a C₁₋₄ alkyl.

Particularly preferably the charge transporting polymer comprises a repeat unit of formula (Xci) or (Xcii):

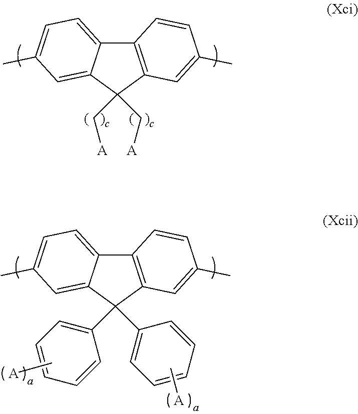

wherein
n is an integer between 1 and 16,
A is a polar group; and
a is an integer from 1 to 5.

Preferably n is an integer between 1 to 6 and yet more preferably an integer between 1 and 4, e.g. 2. Preferably a is 1 or 2. In formula (Xcii) when one A group is present (i.e. a is 1) it is preferably present in the 4 position. In formula (Xcii) when two A groups are present (i.e. a is 2), they are preferably present at the 3 and 4 positions. More preferably the charge transporting polymer comprises a repeat unit of formula (Xcii).

In preferred charge transporting polymers of the invention, the polar group comprises at least one moiety selected from —NHCO—, —NHSO₂—, —COO—, —OCOO—, —NHCOO, —O—, —NR—, —NH—, —NO—, —S—, —CF₂— and —CCl₂— wherein R is C₁₋₈ alkyl. Preferably the polar group comprises at least one —O— moiety, and more preferably a plurality of —O— moeities.

Particularly preferred polar groups present in the charge transporting polymer of the invention are those of formula:

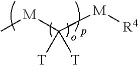

wherein
M is O, NR, NH, S or CQ wherein R is C₁₋₈ alkyl;

### Q is Br, Cl, F, I or H;

### T is Br, Cl, F, I or H;

o is an integer from 1 to 4;
p is an integer from 1 to 16; and
R⁴ is H or C₁₋₆ alkyl.

In preferred groups, M is O, NR or NH, particularly O.

In further preferred groups, T is Cl, F or H, particularly H.

In further preferred groups, o is 2 or 3, particularly 2.

In further preferred groups, p is 1 to 12. In some groups p is more preferably 3 to 10, and still more preferably 4 to 8. In other groups p is more preferably 2 to 6 and still more preferably 2 or 3.

In further preferred groups, R⁴ is H, —CH₃ or —CH₂CH₃.

Yet more preferred polar groups present in the charge transporting polymer of the invention are those of formula:

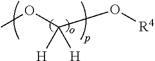

wherein
o is an integer from 1 to 4;
p is an integer from 1 to 16; and
R⁴ is H or C₁₋₆ alkyl.

In preferred groups, o is 2 or 3, particularly 2.

In further preferred groups, p is 1 to 12. In some groups p is more preferably 3 to 10, and still more preferably 4 to 8. In other groups p is more preferably 2 to 6 and still more preferably 2 or 3.

In further preferred groups, R⁴ is H, —CH₃ or —CH₂CH₃.

Especially preferably the polar group present in the charge transporting polymer of the invention comprises at least one —(CH₂CH₂O)— unit.

Particularly preferred charge transporting polymers present in the organic charge transport layer of the present invention comprises a repeat unit of formula (Xcf) or (Xcg):

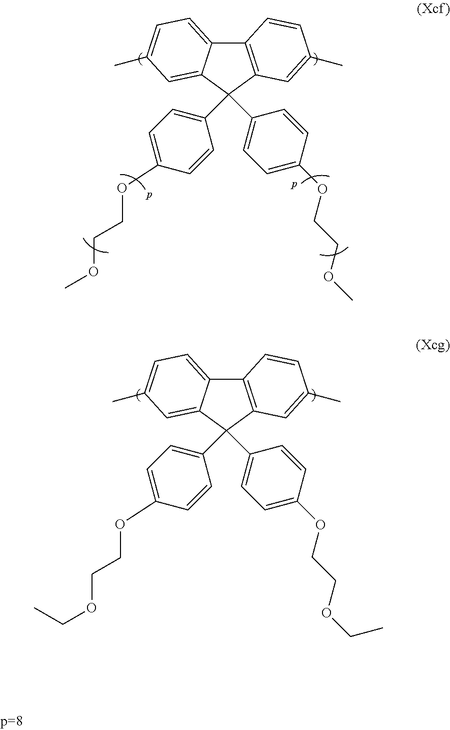

Repeat units of formula (X) may be incorporated into charge transporting polymers using appropriate monomers and methods conventional in the art. The skilled man can determine suitable monomers.

The charge transporting polymer present in the organic charge transport layer of the present invention optionally comprises further repeat units. Some preferred charge transporting polymers comprise a repeat unit of formula (A) which is an substituted or unsubstituted, 2,7-linked fluorene and more preferably a repeat unit of formula (A) as shown below:

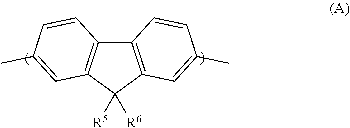

wherein R⁵ and R⁶ are independently selected from hydrogen, unsubstituted or substituted C₁₋₁₆ alkyl, wherein one or more non-adjacent C atoms may be replaced with O, S, N, CO and —COO—, unsubstituted or substituted C₁₋₁₆ alkoxy, unsubstituted or substituted C₅₋₁₄ aryl, unsubstituted or substituted arylalkyl, unsubstituted or substituted C₅₋₁₄ heteroaryl and unsubstituted or substituted heteroarylalkyl. Optional substituents are preferably selected from the group consisting of C₁₋₁₆ alkyl or C₁₋₁₆ cycloalkyl wherein one or more non-adjacent C atoms may be replaced with O, S, N, C═O and —COO—, unsubstituted or substituted C₅₋₁₄ aryl, unsubstituted or substituted C₅₋₁₄ heteroaryl, C₁₋₁₆ alkoxy, C₁₋₁₆ alkylthio, fluorine, cyano and arylalkyl.

In preferred repeat units of formula (A) R⁵ and R⁶ are the same. In particularly preferred repeat units at least one and more preferably both of R⁵ and R⁶ comprise an unsubstituted or substituted C₁₋₁₆ alkyl or an unsubstituted or substituted C₅₋₁₄ aryl, e.g. a C₆ aryl. Preferred substituents of aryl groups are C₁₋₁₆ alkyl and still more preferably an unsubstituted C₁₋₁₆ alkyl group.

Particularly preferred repeat units of formula (A) are shown below. The repeat unit (Ai) is particularly preferred.

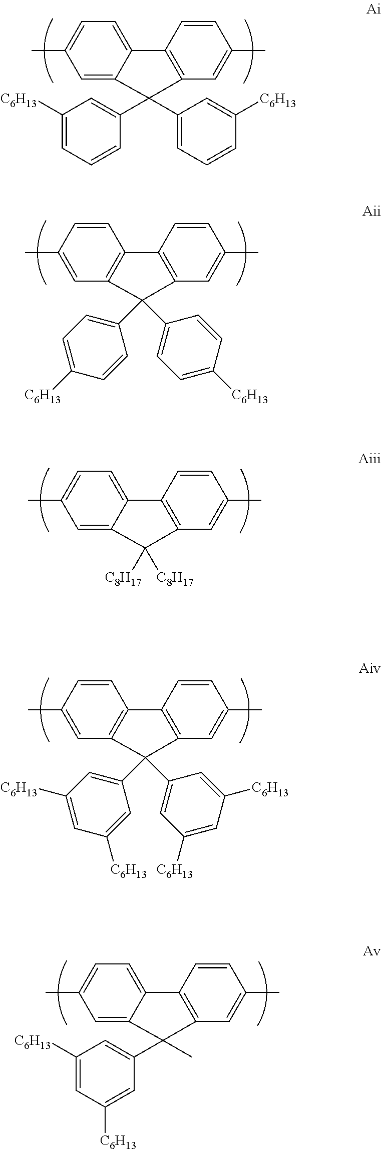

Repeat units of formula (A) may be incorporated into charge transporting polymers using monomers as described in WO2002/092723.

Preferably the charge transporting polymer comprises at least one repeat unit comprising a cross-linkable group. Preferably the at least one repeat unit comprising a cross-linkable group is selected from formulae (Cb):

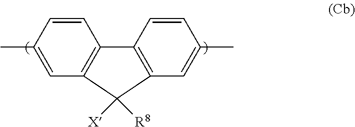

wherein X′ is a cross-linkable group and R⁸ is independently selected from X′, hydrogen, unsubstituted or substituted C₁₋₁₆ alkyl, wherein one or more non-adjacent C atoms may be replaced with O, S, N, CO and —COO—, unsubstituted or substituted C₁₋₁₆ alkenyl, unsubstituted or substituted C₁₋₁₆ alkoxy, optionally substituted C₅₋₁₄ aryl, unsubstituted or substituted arylalkyl, unsubstituted or substituted C₅₋₁₄ heteroaryl and unsubstituted or substituted heteroarylalkyl.

In preferred repeat units of formula (Cb) X′ is a double bond, a triple bond, a precursor capable of in situ formation of a double bond, or an unsaturated heterocyclic group. In some preferred repeat units of formula (Cb) the cross-linkable group X′ is contains a double bond or is a precursor capable of in situ formation of a double bond. More preferably X′ contains —CH═CH₂ group or a benzocyclobutanyl group. Especially preferred X′ groups comprise a C₁₋₁₆ alkyl group, a C₁₋₁₆ alkylidene group or a C₅₋₁₂ aryl group substituted with a benzocyclobutanyl group, particularly preferably C₁₋₁₆ alkyl group substituted with a benzocyclobutanyl group.

In preferred repeat units of formula (Cb) R⁸ is X′. Still more preferably X′ and R⁸ are identical.

Three particularly preferred repeat units of formula (Cb) are shown below. Repeat unit Ci is particularly preferred.

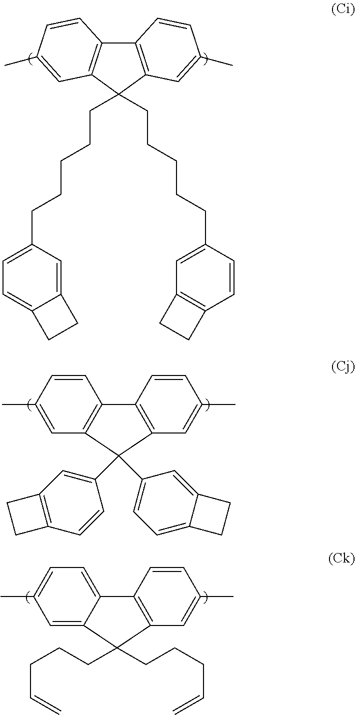

Repeat units of formula (Cb) may be incorporated into charge transporting polymers using monomers as described in WO2002/092723.

In the device of the present invention, the organic charge transport layer has a thickness of 1 nm to 1000 nm. Preferably the organic charge transport layer has a thickness of 5 nm to 800 nm. More preferably the organic charge transport layer has a thickness of 10 nm to 500 nm, still more preferably 15 nm to 100 nm. In more preferred embodiments, the thickness is from 20 to 50 nm. The voltage stability of the organic device depends on the current density. Thinner organic charge transport layers show higher current densities at low voltages. It is therefore preferred for the organic device to comprise an organic charge transport layer having a low thickness so as to allow for higher current densities especially at low voltages.

The organic charge transport layer is deposited by any suitable method. Preferably the organic charge transport layer is deposited by a solution-based processing method, for example printing. Any conventional solution-based processing method may be used. Representative examples of solution-based processing methods include spin coating, gravure printing, dispense printing, nozzle printing, flexographic printing, roll to roll printing, dip coating, slot die coating, doctor blade coating or ink-jet printing and screen printing. The parameters used for spin coating the organic charge transport layer such as spin coating speed, acceleration and time are selected on the basis of the target thickness for the layer. Particularly preferably the organic charge transport layer is deposited by printing and in particular dispense printing, flexographic printing, gravure printing, ink-jet printing, slot die coating or dispense printing. The parameters used for depositing the organic charge transport layer are selected on the basis of the target thickness for the layer.

The electronic device of the present invention optionally comprises an electron injection layer. When present, the electron injection layer is in between the cathode and the organic charge transport layer. Any conventional electron injection layer may be used. For example, electron injection can be enhanced by using conjugated polyelectrolytes, which comprise pendant groups with ionic functionalities (tetra-alkyl ammonium bromide) attached to a conjugated backbone (C. V. Hoven, A. Garcia, G. C. Bazan, and T.-Q. Nguyen, Adv. Mater. 20, 3793 (2008)). For a non-limiting example of suitable organic electron injection layers, see WO2012/133229. The electron injection layer is preferably deposited by a solution-based processing method, for example printing, especially dispense printing. Any conventional solution-based processing method may be used. Representative examples of solution-based processing methods include spin coating, dip coating, dispense printing, gravure printing, nozzle printing, slot die coating, doctor blade coating, ink-jet printing and screen printing. In preferred methods, however, depositing is by dispense printing, screen printing or spin coating, more preferably spin coating. The parameters used for dispense printing, e.g. flow rate, line spacing etc. are selected on the basis of target thickness for the layer. The parameters used for spin coating the organic charge transport layer such as spin coating speed, acceleration and time are selected on the basis of the target thickness for the layer.

In one preferred embodiment, the optional electron injection layer comprises a polymer. Preferably the optional electron injection layer of the present invention comprises a polymer having a repeat unit of formula (Xa) or (Xb):

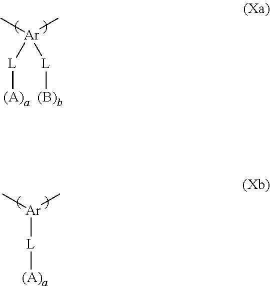

wherein Ar is a C₅₋₂₀ substituted or unsubstituted aryl or heteroaryl group;
L is a bond or a linker group;
A is a polar group; and
B is a polar group, hydrogen, substituted or unsubstituted C₁₋₁₅ alkoxy, substituted or unsubstituted C₅₋₁₄ aryl, substituted or unsubstituted arylalkyl, substituted or unsubstituted C₅₋₁₄ heteroaryl, substituted or unsubstituted heteroarylalkyl and substituted or unsubstituted C₁₋₁₆ alkyl wherein one or more non-adjacent C atoms may be replaced with —O—, —NR—, —NH—, —S—, —COO—, —NHCO—, —NHSO₂—, —NHCOO-groups wherein R is C₁₋₈ alkyl; and
each of a and b are independently an integer selected from 1 to 5

When either of a or b is greater than 1, there are more than 1 A and B groups respectively attached to the linker, e.g. when a is 2, there are 2 A groups attached to the linker. When multiple A and/or B groups are present, they may be attached to the linker at different atoms.

Preferred polymers present in the optional electron injection layer comprise a repeat unit of formula X shown below:

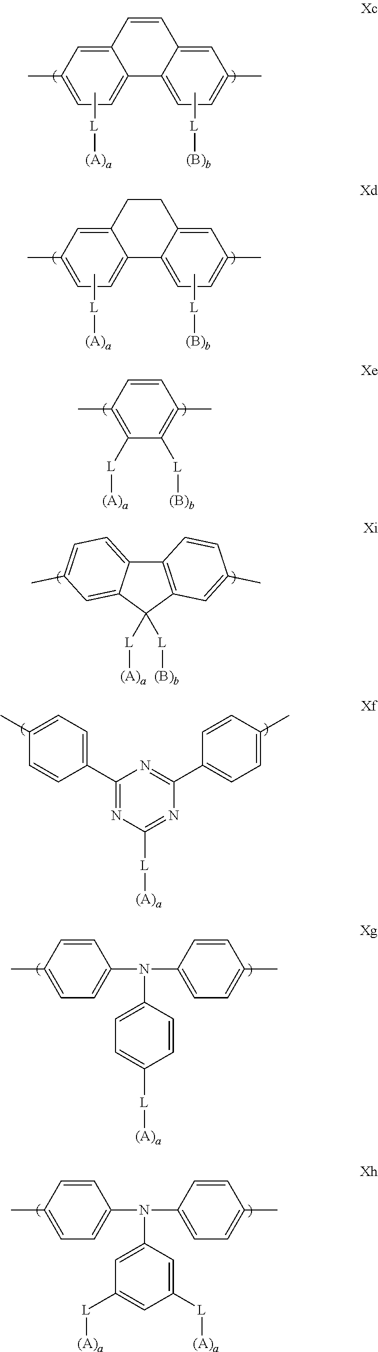

wherein L, A, B, a and b are as defined above in relation to formula Xa and Xb.

Particularly preferably polymer present in the electron injection layer comprises repeat units of formula (Xi):

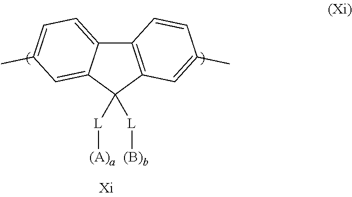

wherein L, A, B, a and b are as defined above in relation to formula Xa and Xb.

In preferred organic electron transport layer polymers, (B)_{b} is (A)ₐ, i.e. the repeat unit comprises identical polar groups per unit. In further preferred organic electron transport layer polymers a is 1 or 2.

In further preferred optional electron injection layer polymers, L is a linker group selected from substituted or unsubstituted C₅₋₁₄ aryl, substituted or unsubstituted C₅₋₁₄ heteroaryl and substituted or unsubstituted C₁₋₁₆ alkyl wherein one or more non-adjacent C atoms may be replaced with —O—, —NR—, —NH—, —S—, —COO—, —NHCO—, —NHSO₂—, —NHCOO-groups wherein R is C₁₋₈ alkyl. More preferably L is a linker group selected from substituted or unsubstituted C₅₋₁₄ aryl and substituted or unsubstituted C₁₋₁₆ alkyl wherein one or more non-adjacent C atoms may be replaced with —O—, —NR—, —NH—, —S—, —COO—, —NHCO—, —NHSO₂—, —NHCOO-groups wherein R is C₁₋₈ alkyl. In some organic electron transport layer polymers, L is a C₅₋₁₄ aryl, especially a C₅ or C₆ aryl, e.g. phenyl. In other organic electron transport layer polymers, L is a C₁₋₁₆ alkyl, more preferably a C₁₋₆ alkyl and yet more preferably a C₁₋₄ alkyl.

Particularly preferably the polymer present in the optional electron injection layer comprises a repeat unit of formula (Xii) or (Xiii):

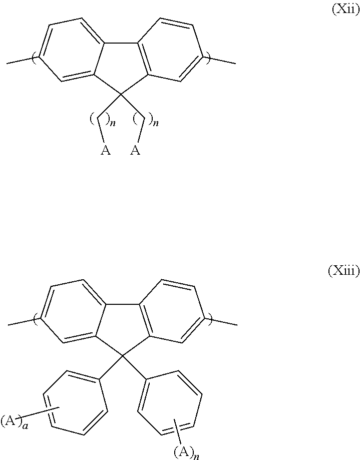

wherein n is an integer between 1 and 16, more preferably an integer between 1 to 6 and yet more preferably an integer between 1 and 4, e.g. 2 and a is 1 or 2. In formula (Xiii) when one A group is present (i.e. a is 1) it is preferably present in the 4 position. In formula (Xiii) when two A groups are present (i.e. a is 2), they are preferably present at the 3 and 4 positions.

In some polymers present in the optional electron injection layer A preferably comprises a zwitterionic group. Preferred zwitterionic groups comprise a positively charged N, P, S or O atom, preferably a positively charged N atom. Particularly preferably the zwitterionic group comprises an oxonium, sulfonium, phosphonium or ammonium, still more preferably an ammonium. Further preferred zwitterionic groups comprise a sulfonate, sulfinate, sulfite, thiosulfate, thiosulfonate, phosphate, phosphite, phosphonate, thiophosphate, thiophosphonate, orthophosphate, pyrophosphate, polyphosphate, carboxy, thiocarboxy or alkoxy group. Sulfonate and carbonate are particularly preferred.

Further preferred zwitterionic groups are those of formula (i):

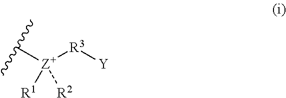

wherein

### Z is N, P, O or S;

R¹ is substituted or unsubstituted C₁₋₈ alkyl, substituted or unsubstituted C₂₋₈ alkenyl, substituted or unsubstituted C₅₋₁₄ aryl or substituted or unsubstituted C₅₋₁₄ heteroaryl;
R² is present when Z is N or P and is R¹;
R³ is a C₁₋₁₀ alkylene chain in which non-adjacent carbon atoms may optionally be replaced by —O—, —NR—, —NH—, —S—, —COO—, —NHCO—, —NHSO₂—, —NHCOO-groups wherein R is C₁₋₈ alkyl; and
Y is SO₃⁻, SO₂⁻, OSO₂⁻, SSO₃⁻, SO₂S⁻, CO₂⁻, PO₃⁻, OPO₃²⁻, OP(OR)O⁻ where R is C1-6 alkyl, OP(S)O₂²⁻, P(S)O₂²⁻, OPO(OH)OPO(OH)O⁻, O—(PO(OH)O)ₙPO(OH)O⁻ wherein n is 1 to 6, CO₂⁻, CSO⁻, or O⁻ group.

In preferred groups of formula (i) Z is N or P, particularly N.

In further preferred groups of formula (i) R¹, and when present R², is an substituted or unsubstituted C₁₋₈ alkyl or substituted or unsubstituted C₅₋₁₄ aryl. More preferably R¹, and when present R², is a C₁₋₆ alkyl, still more preferably a C₁₋₃ alkyl, e.g. methyl.

In further preferred groups of formula (i) R³ is a C₁₋₈ alkyl, more preferably a C₂₋₆ alkyl, e.g. a C₃ or C₄ alkyl.

In further preferred groups of formula (i) Y is SO₃⁻ or CO₂⁻.

In some polymers present in the electron injection layer A comprises a non-charged polar group. Preferred examples of such polar groups include amide, sulfonamide, ester, carboxylic acid, carbonate, carbamate, ether, alcohol, amine, thioether, sulfide or haloalkyl. Particularly preferred polar groups are those of formula (ii):

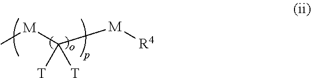

wherein
M is O, NR, NH, S or CQ wherein R is C₁₋₈ alkyl;
Q is Br, Cl, F, I or H, preferably Cl, F or H;

### T is Br, Cl, F, I or H;

o is an integer from 1 to 4;
p is an integer from 1 to 16; and
R⁴ is H or C₁₋₆ alkyl.

In preferred groups of formula (ii), M is O, NR or NH, particularly O.

In further preferred groups of formula (ii), T is Cl, F or H, particularly H.

In further preferred groups of formula (ii), o is 2 or 3, particularly 2.

In further preferred groups of formula (ii), p is 1 to 12. In some groups p is more preferably 3 to 10, and still more preferably 4 to 8. In other groups p is more preferably 2 to 6 and still more preferably 2 or 3.

In further preferred groups of formula (ii), R⁴ is H, —CH₃ or —CH₂CH₃.

In some polymers present in the electron injection layer of the present invention A comprises an ionic group. Preferred ionic groups comprise a covalently bound anion, particularly a covalently bound anion selected from SO₃⁻, SO₂⁻, OSO₂⁻, SSO₃⁻, SO₂S⁻, CO₂⁻, PO₃⁻, OPO₃²⁻, OP(OR)O⁻ where R is C₁₋₆ alkyl, OP(S)O₂²⁻, P(S)O₂²⁻, OPO(OH)OPO(OH)O⁻, O—(PO(OH)O)ₙPO(OH)O⁻ wherein n is 1 to 6, CO₂⁻, C(S)O⁻, or O⁻. Still more preferably the covalently bound anion is CO₂⁻.

Preferably the ionic group comprises a counter cation selected from Li⁺, Na⁺, K⁺, Rb⁺, Cs⁺, Be²⁺, Mg²⁺, Ca²⁺, Sr²⁺ and Ba²⁺. Still more preferably the cation is Cs⁺.

Particularly preferred polymers present in the electron injection layer optionally present in the electronic device of the present invention comprise a repeat unit of formula (Xii) and still more preferably a repeat unit of formula (Xii) wherein a is 1. In such polymers A is preferably a zwitterionic group.

Other particularly preferred polymers present in the electron injection layer optionally comprise a repeat unit of formula (Xiii) and still more preferably a repeat unit of formula (Xiii) wherein a is 1. In such polymers A is preferably a non-charged polar group.

Other particularly preferred polymers present in the optional electron injection layer comprise a repeat unit of formula (Xiii) and still more preferably a repeat unit of formula (Xiii) wherein a is 2. In such polymers one A is preferably a non-charged polar group and one A is preferably an ionic group.

Particularly preferred polymers present in the optional electron injection layer comprises a repeat unit of formula (Xiv), (Xv), (Xvi) or (Xvii):

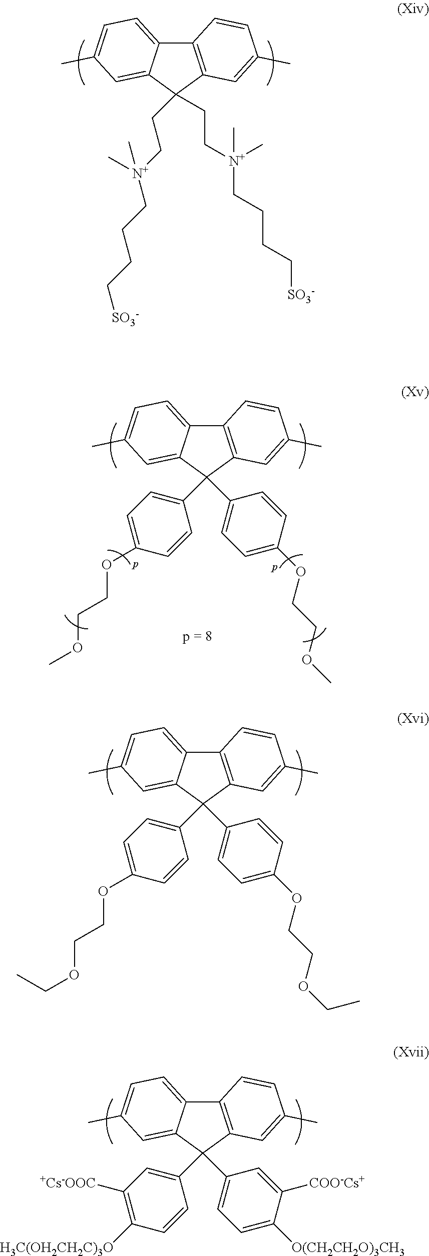

The polymer present in the optional electron injection layer of the present invention optionally comprises further repeat units. Some preferred polymers comprise a repeat unit of formula (R) which is an substituted or unsubstituted, 2,7-linked fluorene and more preferably a repeat unit of formula (R) as shown below:

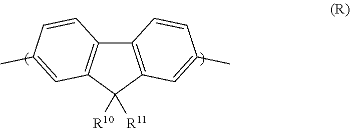

wherein R¹⁰ and R¹¹ are independently selected from hydrogen, substituted or unsubstituted C₁₋₁₆ alkyl, substituted or unsubstituted C₁₋₁₆ alkoxy, substituted or unsubstituted C₅₋₁₄ aryl, substituted or unsubstituted arylalkyl, substituted or unsubstituted C₅₋₁₄ heteroaryl and substituted or unsubstituted heteroarylalkyl.

In preferred repeat units of formula (R) R¹⁰ and R¹¹ are the same. In particularly preferred repeat units at least one and more preferably both of R¹⁰ and R¹¹ comprise a substituted or unsubstituted C₁₋₁₆ alkyl or a substituted or unsubstituted C₅₋₁₄ aryl, e.g. a C₆ aryl. Preferred substituents of aryl groups are C₁₋₁₆ alkyl and still more preferably an unsubstituted C₁₋₁₆ alkyl group.

A particularly preferred repeat unit of formula (R) for use in the electron injection layer polymer is (Ri) as shown below:

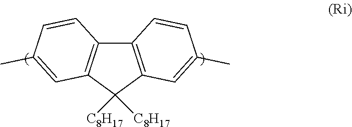

Repeat units of formula (R) may be incorporated into the electron injection layer polymers using monomers as described in WO2002/092723.

A particularly preferred optional electron injection layer polymer is (Xvii) as shown below:

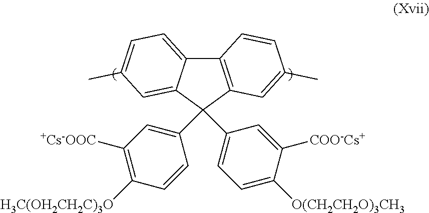

This material and its synthesis are described in US2012/181529, WO2012/3214 and WO2012/133219.

In another preferred embodiment, the optional electron injection layer comprises an alkali-metal halogenide, such as a flouride, bromide, chloride or iodide. More preferred are alkali-metal fluorides. Most preferred is the optional electron injection layer comprising NaF.

A further aspect of the invention is a method of making an electronic device comprising the steps of:
providing an anode layer;
depositing a work function modification layer comprising a Cs compound;
depositing an organic charge transporting layer;
optionally depositing an electron injection layer; and
depositing a cathode layer.

In the method of the present invention the organic layer is a charge transporting layer and is deposited on a surface by a solution-based processing method, for example printing, especially dispense printing. Any conventional solution-based processing method may be used. Representative examples of solution-based processing methods include spin coating, dip coating, dispense printing, gravure printing, nozzle printing, slot die coating, doctor blade coating, ink-jet printing and screen printing. In preferred methods, however, depositing is by dispense printing, screen printing or spin coating. The parameters used for dispense printing, e.g. flow rate, line spacing etc. are selected on the basis of target thickness for the layer. The parameters used for spin coating the charge transport layer such as spin coating speed, acceleration and time are selected on the basis of the target thickness for the layer. Preferably the charge transport layer is deposited by printing and in particular dispense printing or screen printing.

In the method of the present invention, the optional electron injection layer is preferably deposited by a solution-based processing method, for example printing, especially dispense printing. Any conventional solution-based processing method may be used. Representative examples of solution-based processing methods include spin coating, dip coating, dispense printing, gravure printing, nozzle printing, slot die coating, doctor blade coating, ink-jet printing and screen printing. In preferred methods, however, depositing is by dispense printing, screen printing or spin coating, more preferably spin coating. The parameters used for dispense printing, e.g. flow rate, line spacing etc. are selected on the basis of target thickness for the layer. The parameters used for spin coating the charge transporting layer such as spin coating speed, acceleration and time are selected on the basis of the target thickness for the layer.

In a further preferred embodiment of the method of the invention, the cathode layer is deposited by vapour deposition. In another preferred method of the invention the cathode layer is deposited by printing, e.g. by screen printing, gravure printing, flexigraphic printing, roll to roll printing or ink-jet printing. More preferably the cathode layer is deposited by screen printing. Printing, e.g. screen printing, is carried out by conventional techniques in the art. Preferably the ink is applied to an optionally patterned mesh placed on the surface of an organic charge transportlayer or organic electron transport layer and a squeegee or blade is applied to force the ink through the mesh.

In a preferred method of the present invention, if the cathode layer is deposited by screen printing, it is dried and/or cured following deposition on the charge transporting or electron injection layer. Drying and/or curing is preferably carried out by heating with a box oven, an IR oven or a hot plate. During the drying and/or curing process, the solvent is evaporated and a matrix comprising the carbon particles is formed. The heating also causes the conductive carbon particles present to coalesce to form a conductive track. The skilled man is readily able to determine suitable drying and/or curing conditions.

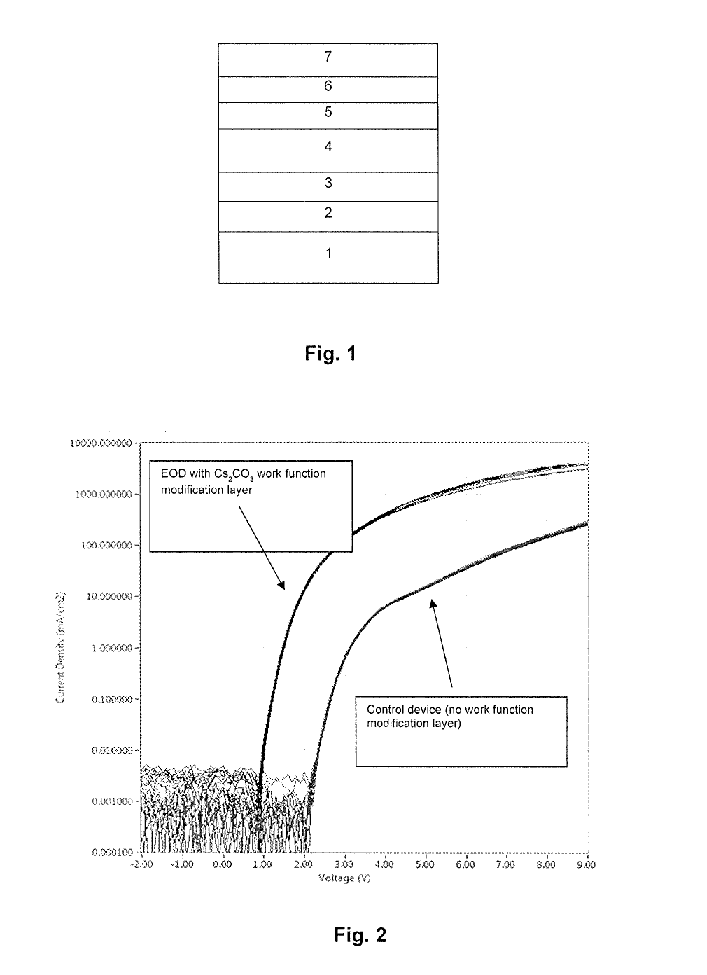

With reference to Figures, a cross-section through a basic structure of a typical device in accordance with the present invention is shown in FIG. 1. A glass or plastic substrate 1 supports an anode 2 comprising, for example, ITO. A work function modification layer 3 comprising a Cs compound is present on the anode layer. An organic charge transport layer 4 is present on the anode layer. An optional electron injection layer is shown as layer 5. Finally a cathode 6 is formed on top thereof, followed by an encapsulation layer 7. Not shown are contact wires to the anode and the cathode which respectively provide a connection to a power source.

Electronic devices tend to be sensitive to moisture and oxygen. Accordingly, if present, the optional substrate has preferably good barrier properties for prevention of ingress moisture and oxygen into the device. Suitable encapsulants include a sheet of glass, films having a suitable barrier properties such as alternating stacks of polymer and dielectric disclosed in, for example, WO 01/81649 or an airtight container as disclosed in WO 01/19142.

A work function modification layer comprising a Cs compound deposited on an anode such as ITO works as an efficient hole blocking layer for making electronic devices, in particular electron only devices, by completely preventing hole injection and thereby light emission. The electronic device of the present invention shows low turn-on voltages (<1 V), high current densities (up to 1 A/cm² at 4 V), and excellent rectification ratios of up to 10⁶ at 2 V.

Advantageously, the organic electronic device of the present invention may be used in applications such as a rectifier diode integrated with OLEDs and/or organic photo detector pixels. The materials used in the organic electronic device of the present invention comprise the same or similar materials for current rectification which are also used in the respective LEDs or pixel LEDs. This results in better performance and allows for higher current densities, in particularly in n-type diodes.

### EXAMPLES

The invention will be illustrated by way of examples, which are intended to illustrate the invention without limiting the invention thereto.

### Example 1

An organic rectifier diode—Electron Only Device structure is shown in FIG. 1. It is based on a standard OLED structure where the hole injection layer and hole transport layer are replaced with a work function modification layer 3.

A Cs₂CO₃ work function modification layer is spun from 2-butoxyethanol or 2-butoxyethanol:methanol (50:50 blend) solution The concentration of Cs₂CO₃ in the solution is about 0.2 wt %, providing a layer thickness of about 3 nm. After spinning, the Cs₂CO₃ work function modification layer is dried at 120 C.° for 10 minutes. An organic charge transport layer 4 is applied on the work function modification layer, the organic charge transport layer comprising a fluorene-based electron-transporting polymer. O top thereof, an electron injection layer 5 of NaF is applied, which provides efficient electron injection into the organic charge transport layer.

Finally, an Al cathode layer 6 is applied on top thereof and the obtained device is encapsulated.

Electron Only Device performance

FIG. 2 displays the current density vs. voltage graphs for EODs in which Cs₂CO₃ is used as a work function modification layer. Also shown are the results for a control device of the same structure but without a work function modification layer.

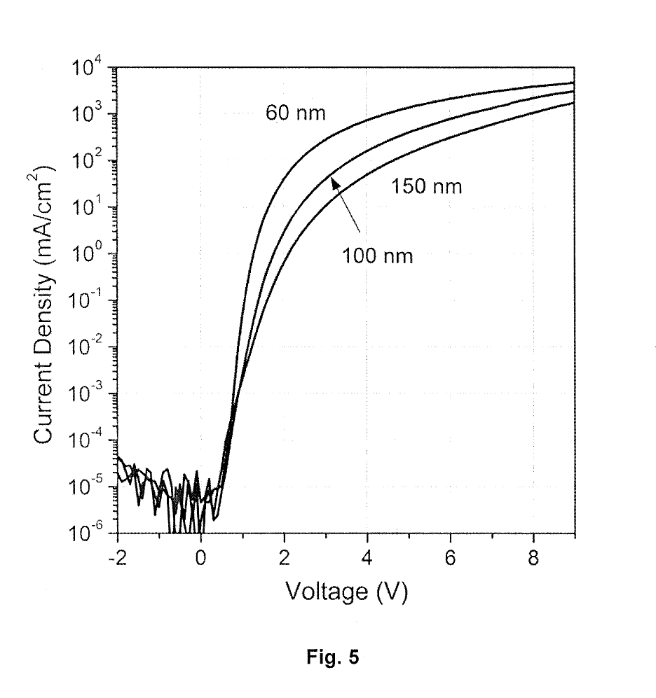

The obtained devices with a Cs₂CO₃ work function modification layer demonstrate low turn-on voltage (<1 V), high current density, and complete absence of light emission. By contrast, the control devices without a work function modification layer show a much higher turn-on voltage and some light emission. Rectification ratio of EODs with a Cs₂CO₃ work function modification layer is up to 10⁶ at 2 V (restricted by lateral leakage current, see FIG. 5).

The turn-on voltage of EODs is defined by the workfunctions of the ITO anode and the cathode. The work function of ITO is modified (decreased) by deposition of Cs₂CO₃ through surface dipole formation, which results in significant decrease of the turn-on voltage. The hole blocking mechanism in EODs with Cs₂CO₃ work function modification layer is a significant increase of the barrier height for hole injection as a result of the decrease of the ITO workfunction.

As the ITO workfunction modification mechanism is surface dipole formation, the layer of Cs₂CO₃ can be made very thin (down to one monolayer if desired). Thinner work function modification layer may be beneficial for device storage stability due to a decrease of the amount of mobile Cs⁺ ions which may diffuse to the organic layer and affect its transport properties.

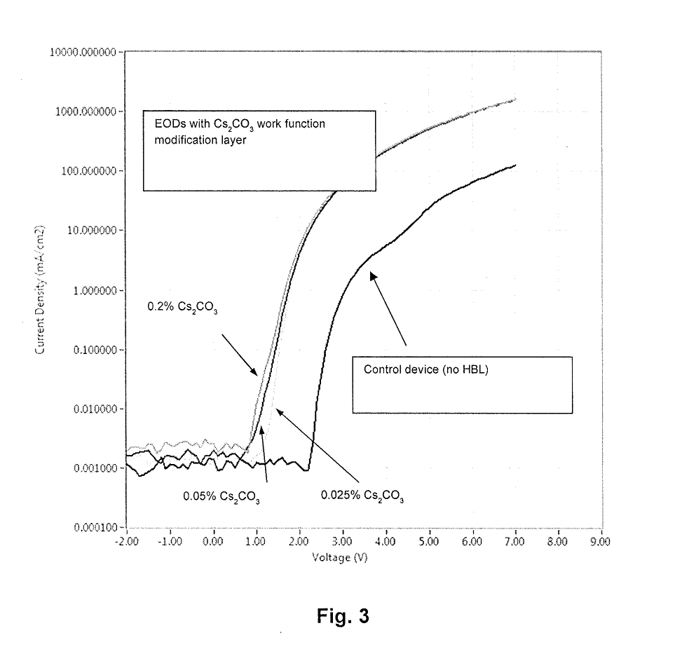

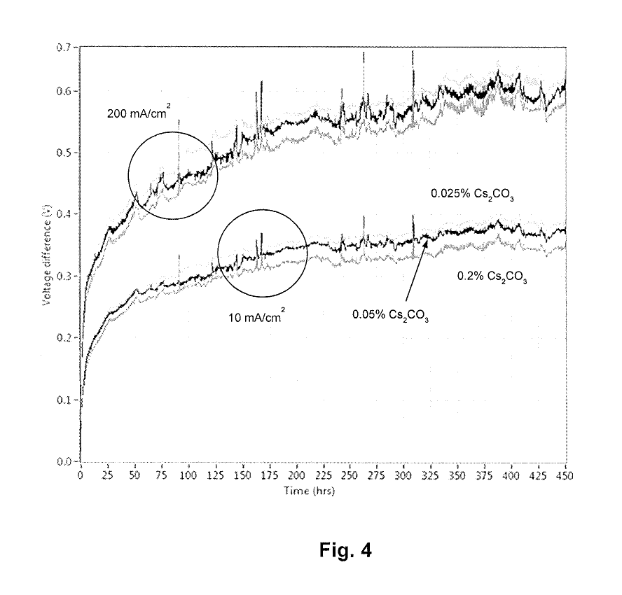

FIG. 3 shows the current density vs. voltage graphs for EODs with various Cs₂CO₃ layer thicknesses. As layer thicknesses below 5 nm cannot be easily measured using standard techniques (Dektak profilometer), solution concentration variation was used to spin thinner layers. It is clearly seen that even for the thinnest work function modification layer spun from a 0.025% solution of Cs₂CO₃, the turn-on voltage is still low (and no light emission is observed).

FIG. 4 shows the voltage stability of EODs with time at two different fixed current densities. It can be seen that stability depends on current density but not on the Cs₂CO₃ layer thickness (layer thickness decreases with decreasing Cs₂CO₃ content in the solution). Fast initial voltage rise on a timescale of few tens of hours is observed followed by a plateau on a timescale of at least hundreds of hours.

FIG. 5 shows current density vs. voltage graphs for EODs with various organic charge transport layer thicknesses. Thinner devices have higher current densities at low voltages reaching 1 A/cm² at 4 V for organic charge transport layer thickness of 60 nm.

All evaluations were carried out at 20° C. using for the voltage stability test a Keithley 2401 or Keithley 2400 device. Performance evaluations were carried out with an 8-channel Botest LIV functionality system from Botest System GmbH, employing a voltage range of −5 to +7 V using 100 mV steps of 400 ms, of which 300 ms are a delay and 100 ms are used for averaging. As indicated above, the control device has the same structure as the devices in accordance with the present invention as evaluated herewith, with the only exception that the work function modification layer is omitted.

The evaluation as carried out proves that electron only devices in accordance with the present invention provide improved performance when compared with the control device.

1. An electronic device comprising:
an anode layer;
a work function modification layer comprising a salt compound selected among alkali metal salts, and salts with organic cations comprising at least 3 carbon atoms, such as tetraalkylammonium salts, tetraalkylphosphonium salts, trialkylsulfonium salts, pyridinium salts and immidazolium salts in contact with the anode layer and operable to decrease the workfunction of the anode layer to block hole injection from the anode;
an organic charge transport layer;
an optional electron injection layer; and
a cathode layer.

2. The device of claim 1, wherein the salt compound of the work function modification layer is an alkali metal salt selected from lithium salts, sodium salts, potassium salts, rubidium or cesium salts.

3. The device of claim 2, wherein the salt compound is a carbonate, carboxylate, dihydrogen phosphate, hydrogen phosphate, and phosphate or phosphonate.

4. The device of claim 1, wherein the salt compound of the work function modification layer is selected from the group consisting of alkali metal carbonates.

5. The device of claim 1, wherein the salt compound of the work function modification layer is Cs₂CO₃.

6. The device of claim 1, wherein the anode layer comprises indium tin oxide.

7. The device of claim 1, comprising an electron injection layer which comprises an alkali-metal halogenide.

8. The device of claim 1, wherein the work function modification layer has a thickness of 10 nm or less.

9. The device of claim 1, wherein the organic charge transport layer comprises a polymer comprising fluorene repeating units.

10. The device of claim 9, wherein the polymer comprises a repeat unit of the following formula (IIIa): 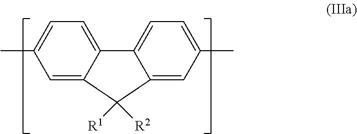
wherein R¹ and R² are the same or different and each is selected from the group consisting of hydrogen, an alkyl group having from 1 to 16 carbon atoms, an aryl group having from 5 to 14 carbon atoms and a 5- to 7-membered heteroaryl group containing from 1 to 3 sulfur atoms, oxygen atoms and/or nitrogen atoms, said aryl group or heteroaryl group being unsubstituted or substituted with one or more substituents selected from an alkyl group having from 1 to 16 carbon atoms and an alkoxy group having from 1 to 16 carbon atoms.

11. The device of claim 1, wherein the device is a rectifier diode which does not emit light in operation.

12. The device of claim 11 wherein the device conducts only electrons in use.

13. A method of producing the device of claim 1 comprising the steps of:
providing an anode layer;
depositing a work function modification layer comprising a salt compound selected among alkali metal salts, and salts with organic cations comprising at least 3 carbon atoms, such as tetraalkylammonium salts, tetraalkylphosphonium salts, trialkylsulfonium salts, pyridinium salts and immidazolium salts;
depositing an organic charge transport layer;
optionally depositing an electron injection layer; and
depositing a cathode layer.

14. A method as claimed in claim 13 in which the work function modification layer and organic charge transport layer are deposited from solution.
